(19) United States
(12) Patent Application Publication
(10) Pub. No.: US 2025/0347472 A1
(43) Pub. Date: Nov. 13, 2025

(54) COMBINED HEAT DISSIPATION STRUCTURE

(71) Applicant: ASIA VITAL COMPONENTS CO., LTD., NEW TAIPEI CITY (TW)

(72) Inventors: KUO SHENG LIN, NEW TAIPEI CITY (TW); JIGANG LI, NEW TAIPEI CITY (TW)

(21) Appl. No.: 18/777,781

(22) Filed: Jul. 19, 2024

(30) Foreign Application Priority Data
May 7, 2024 (TW) 113116862

(51) Int. Cl. F28D 15/02; F28D 15/04

(52) U.S. Cl. CPC F28D 15/0275; F28D 15/046

(57) ABSTRACT

A combined heat dissipation structure includes a vapor chamber and at least one heat pipe. The vapor chamber includes an upper plate and a lower plate. A plate chamber is defined between the upper and lower plates. A first wick structure and a working fluid are provided in the plate chamber. The upper plate has at least one through hole communicating with the plate chamber and an annular flange protruding from the through hole toward the upper plate. The annular flange has a first positioning portion. The heat pipe has two ends defined as a closed end and an open end. A second positioning portion is formed on the heat pipe close to the open end. The second positioning portion is engaged with the first positioning portion, so that the heat pipe and the vapor chamber can be combined quickly, accurately.

### FIELD OF THE INVENTION

The present invention relates to a combined heat dissipation structure, and more particularly to a combined heat dissipation structure that can position and combine a heat pipe and a vapor chamber accurately.

### BACKGROUND OF THE INVENTION

As technology advances, the number of transistors per unit area of an electronic component is increasing, and its operating frequency is also getting higher and higher. The heat generated by the operation of transistors is the cause of increased heat generation in electronic components. Failure to remove the heat quickly will result in a reduction of the chip's computing speed and, in severe cases, the service life of the chip. In order to enhance the heat dissipation effect of electronic components, passive heat sinks, heat pipes and vapor chambers are generally used for heat dissipation, such that the heat is dissipated by heat exchange between the fins of the heat sinks and the external environment.

A vapor chamber consists of a platy casing and a wick structure in the inner chamber of the casing. The casing is filled with a working fluid. One side (i.e., the evaporation region) of the casing, is attached to a heat-generating element (such as a central processing unit, a north-south bridge chip, a transistor, etc.) to absorb the heat generated by the heat-generating element, such that the liquid working fluid is vapored in the evaporation region due to heat evaporation. The heat is introduced to the condensation zone of the casing by means of vapor. The vapored working fluid is cooled in the condensation zone and condensed to become a liquid. Then, the liquid working fluid flows back to the evaporation zone through gravity or the wick structure to continue the vapor-liquid cycle, so as to achieve the effect of constant temperature heat dissipation. Heat pipes work on the same principle as vapor chambers. A heat pipe mainly includes a round pipe. The hollow part of the pipe is filled with a metal powder, and a wick structure is formed on the inner wall of the pipe by sintering. The pipe is evacuated, filled with a working fluid, and finally closed to form a heat pipe structure. When in use, the working fluid is heated and vapored at the evaporation end and then introduced to the condensation end of the heat pipe.

The heat conduction of vapor chambers and heat pipes are not the same. The heat conduction of a vapor chamber is two-dimensional (point-to-surface) heat conduction. The heat conduction of a heat pipe is one-dimensional (point-to-point) heat conduction. In general, the heat dissipation efficiency of the vapor chamber is much higher than that of the heat pipe. However, in these days, the heat dissipation requirements of electronic components are increasing, and it is no longer sufficient to use only a single heat pipe or vapor chamber. Therefore, the application of this field has been developed to combine a heat pipe and a vapor chamber into one to improve the heat conduction efficiency of the entire electronic device, so as to solve the heat dissipation problem of electronic components with increasing power.

Referring to FIG. 1 through FIG. 4, as to the combination of a vapor chamber and a heat pipe, the upper plate 101 of the vapor chamber 10 is formed with a through hole 102. The open end 110 of the heat pipe 11 is inserted into the through hole 102 and joined to the vapor chamber 10, such that the heat pipe chamber 111 communicates with the vapor chamber 103. After completing the above-mentioned plug-in connection, it is necessary to make sure that the internal wick microstructures 104, 112 of the heat pipe 11 and the vapor chamber 10 are also connected together to form an internal working fluid loop. After that, the outer casing of the heat pipe 11 and the casing of the vapor chamber 10 are welded, sealed and fixed. However, the plug-in connection between the heat pipe and the vapor chamber has to be done manually and then welded. When the heat pipe 11 is to be inserted in the through hole 102 for joining, the depth of insertion cannot be precisely determined due to the difference in insertion force each time. As a result, it is unable to achieve consistent and precise positioning of the plug-in connection between the heat pipe and the vapor chamber. If the heat pipe 11 is inserted too deeply by means of a blind-mate connection (as shown in FIG. 1 and FIG. 2), the open end 110 of the heat pipe 11 is in tight contact with the inner bottom surface of the lower plate 105 of the vapor chamber 10 or damages the internal wick microstructure 104. As a result, the heat pipe chamber 111 cannot communicate with the vapor chamber 103, and the internal working fluid cannot be cycled. If the heat pipe is skewed or the depth is not enough (as shown in FIG. 3 and FIG. 4), the wick microstructure 104, 112 of the heat pipe 11 and the vapor chamber 10 are not in better contact with each other, which will affect the return efficiency of the working fluid and the heat conduction efficiency greatly.

Accordingly, the inventor of the present invention has devoted himself based on his many years of practical experiences to solve these problems.

### SUMMARY OF THE INVENTION

The primary object of the present invention is to provide a combined heat dissipation structure, which comprises a vapor chamber and at least one heat pipe each having a positioning portion so that the vapor chamber and the heat pipe can be aligned accurately and assembled quickly to improve the heat dissipation of the heat pipe and vapor chamber.

Another object of the present invention is to provide a combined heat dissipation structure, which can accurately combine the vapor chamber with the heat pipe in a quick manner to save the assembly time, and a support force is formed between the two combined parts to assist in positioning for subsequent welding and other reprocessing.

In order to achieve the foregoing objects, the combined heat dissipation structure provided by the present invention comprises a vapor chamber and at least one heat pipe. The vapor chamber includes an upper plate and a lower plate. The lower plate is covered by the upper plate. A plate chamber is defined between the upper plate and the lower plate. A first wick structure is provided in the plate chamber. The plate chamber is filled with a working fluid. The upper plate has at least one through hole communicating with the plate chamber. An annular flange protrudes from the outer periphery of the through hole toward the upper plate. The annular flange has a first positioning portion on an inner circumferential surface of the annular flange. The heat pipe has a heat pipe chamber therein. The heat pipe chamber communicates with the plate chamber. The heat pipe has two ends defined as a closed end and an open end. A second positioning portion is formed on an outer circumferential surface of the heat pipe close to the open end and corresponds in position to the second positioning portion. When the open end of the heat pipe is inserted into the vapor chamber, the second positioning portion is engaged with the first positioning portion, so as to ensure the accurate depth and direction of the heat pipe to be inserted in the vapor chamber.

In a feasible embodiment, when the second positioning portion is engaged with the first positioning portion, a length between the second positioning portion and the open end is predetermined for the heat pipe chamber to communicate with the plate chamber. A second wick structure is provided in the heat pipe chamber. When the second positioning portion is engaged with the first positioning portion, the second wick structure of the heat pipe gets better contact with the first wick structure of the vapor chamber. The first wick structure and the second wick structure are selected from one of a sintered powder structure, a woven mesh, a grid and a fiber bundle. The first wick structure and the second wick structure may be the same or different wick structures.

In a feasible embodiment, the first positioning portion is an annular convex portion formed on the inner circumferential surface of the annular flange and protruding toward the center of the annular flange. The second positioning portion is an annular concave portion that is formed on the outer circumferential surface of the heat pipe close to the open end and corresponds in position to the first positioning portion. When the open end of the heat pipe is inserted into the vapor chamber, the second positioning portion is engaged with the first positioning portion, so that the heat pipe won't be displaced or pulled out relative to the vapor chamber by an external force.

In a feasible embodiment, the first positioning portion is an annular concave portion formed on the inner circumferential surface of the annular flange, and the second positioning portion is an annular convex portion formed on the outer circumferential surface of the heat pipe close to the open end.

With the above technical solution, the present invention can accurately combine and position the vapor chamber and the heat pipe in a quick manner, simplify the assembly operation, and prevent the heat dissipation of the heat pipe and vapor chamber from being affected due to inaccurate manual alignment or blind-mate connection.

### BRIEF DESCRIPTION OF THE DRAWINGS

FIG. 1 is a schematic view showing a conventional combination of a heat pipe and a vapor chamber, wherein the heat pipe is inserted too deeply to damage the wick structure on the inner bottom surface of the vapor chamber;

FIG. 1A is an enlarged view of circle A in FIG. 1;

FIG. 2 is another schematic view showing a conventional combination of a heat pipe and a vapor chamber, wherein the heat pipe is inserted too deeply;

FIG. 3 is a further schematic view showing a conventional combination of a heat pipe and a vapor chamber, wherein when the depth that the heat pipe is inserted in the vapor chamber is not enough, the internal wick structure of the heat pipe is not in contact with the internal wick structure of the vapor chamber;

FIG. 3A is an enlarged view of circle A in FIG. 3;

FIG. 4 is a yet further schematic view showing a conventional combination of a heat pipe and a vapor chamber, wherein the depth that the heat pipe is inserted in the vapor chamber is not enough and the heat pipe is skewed;

FIG. 5 is an exploded view according to a first embodiment of the present invention;

FIG. 6 is a cross-sectional view of FIG. 5;

FIG. 7 is a cross-sectional view according to a second embodiment of the present invention before being assembled;

FIG. 8 is a cross-sectional view according to the second embodiment of the present invention after being assembled;

FIG. 9 is an exploded view according to a third embodiment of the present invention;

FIG. 10 is a cross-sectional view of FIG. 9;

FIG. 11 is a schematic view showing the second positioning portion and the first positioning portion according to a fourth embodiment of the present invention before assembly;

FIG. 12 and FIG. 13 are schematic views showing the assembly process of the second positioning portion and the first positioning portion according to a fifth embodiment of the present invention;

FIG. 14 is a schematic view showing that the second positioning portion and the first positioning portion are joined according to a sixth embodiment of the present invention; and

FIG. 14A is an enlarged view of circle A in FIG. 14.

### DETAILED DESCRIPTION OF THE PREFERRED EMBODIMENTS

Embodiments of the present invention will now be described, by way of example only, with reference to the accompanying drawings.

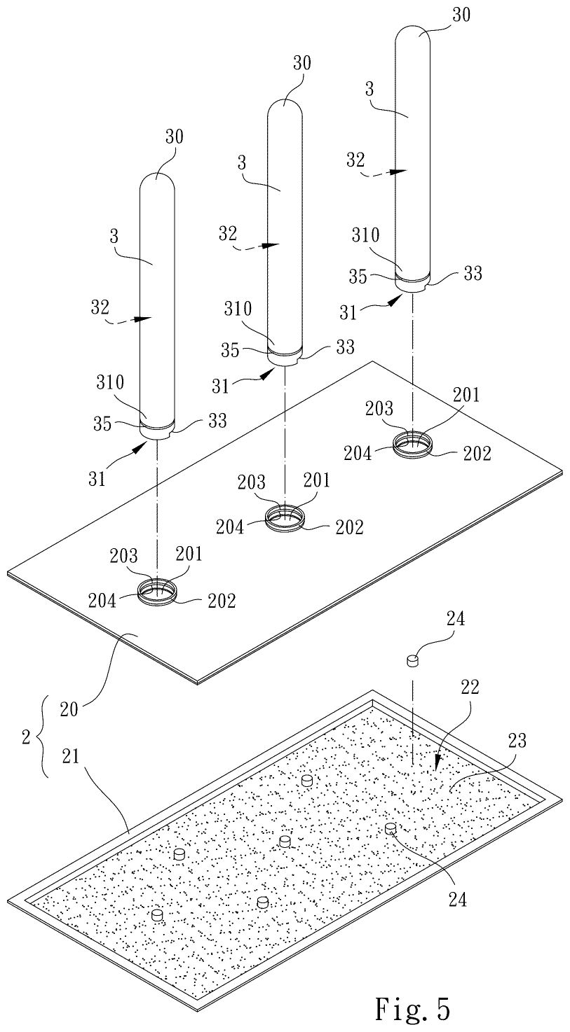

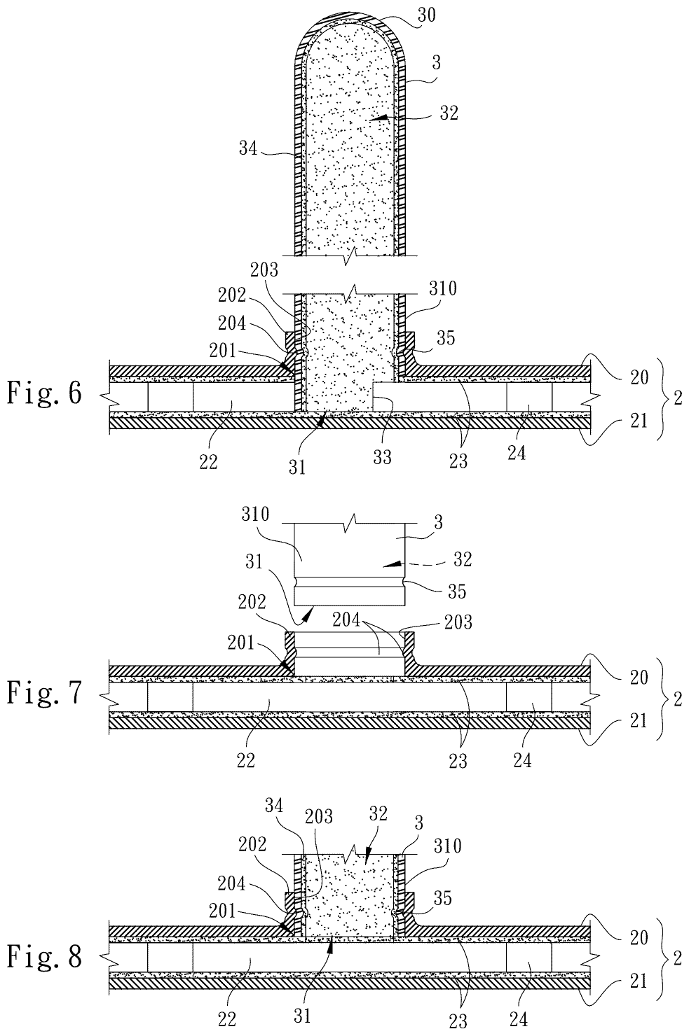

FIG. 5 is an exploded view according to a first embodiment of the present invention. FIG. 6 is a cross-sectional view of FIG. 5. As shown in FIG. 5 and FIG. 6, the present invention discloses a combined heat dissipation structure, comprising a vapor chamber 2 and at least one heat pipe 3. The vapor chamber 2 includes an upper plate 20 and a lower plate 21. The lower plate 21 is covered by the upper plate 20. A plate chamber 22 is defined between the upper plate 20 and the lower plate 21. A first wick structure 23 and/or a plurality of support members 24 or capillary members 25 are provided in the plate chamber 22. The plate chamber 22 is filled with a working fluid (not shown). The upper plate 20 has at least one through hole 201 communicating with the plate chamber 22. An annular flange 202 protrudes from the outer periphery of the through hole 201 toward the upper plate 20. The inner surface of the lower plate 21 of the vapor chamber 2 is defined as an evaporation region of the vapor chamber 2.

The heat pipe 3 has two ends defined as a closed end 30 and an open end 31. A heat pipe chamber 32 is defined in the heat pipe 3. The open end 31 may have a notch 33. A second wick structure 34 is provided inside the heat pipe 3. The open end 31 is insertedly connected to the annular flange 202 and extends into the through hole 201, so that the heat pipe chamber 32 communicates with the plate chamber 22.

As shown in the drawings of the present invention, a first positioning portion 204 is formed on an inner circumferential surface 203 of the annular flange 202 disposed on the upper plate 20 of the vapor chamber 2. A second positioning portion 35 is formed on an outer circumferential surface 310 of the heat pipe 3 close to the open end 31. The second positioning portion 35 corresponds in position to the first positioning portion 204. When the open end 31 is insertedly connected to the annular flange 202, the second positioning portion 35 is engaged with the first positioning portion 204, and the length between the second positioning portion 35 and the open end 31 is just enough to allow the first wick structure 23 or the capillary members 25 to get better contact with the second wick structure 34, and the open end 31 is located between the first positioning portion 20 and the first wick structure 23 on the lower plate 21. In this way, the open end 31 of the heat pipe 3 is confined by means of the engagement (embedded connection, snap-fit connection or screw connection) of the first positioning portion 204 and the second positioning portion 35. This can prevent the open end 31 of the heat pipe 3 from being inserted too much or too little into the vapor chamber 2. In order to ensure that the heat pipe 3 and the vapor chamber 2 are connected accurately, uprightly without being skewed, the first positioning portion 204 and the second positioning portion 35 may be connected through at least three points formed around the respective circumferences, thereby guiding the plug-in connection between the heat pipe 3 and the vapor chamber 2 to avoid inaccurate insertion.

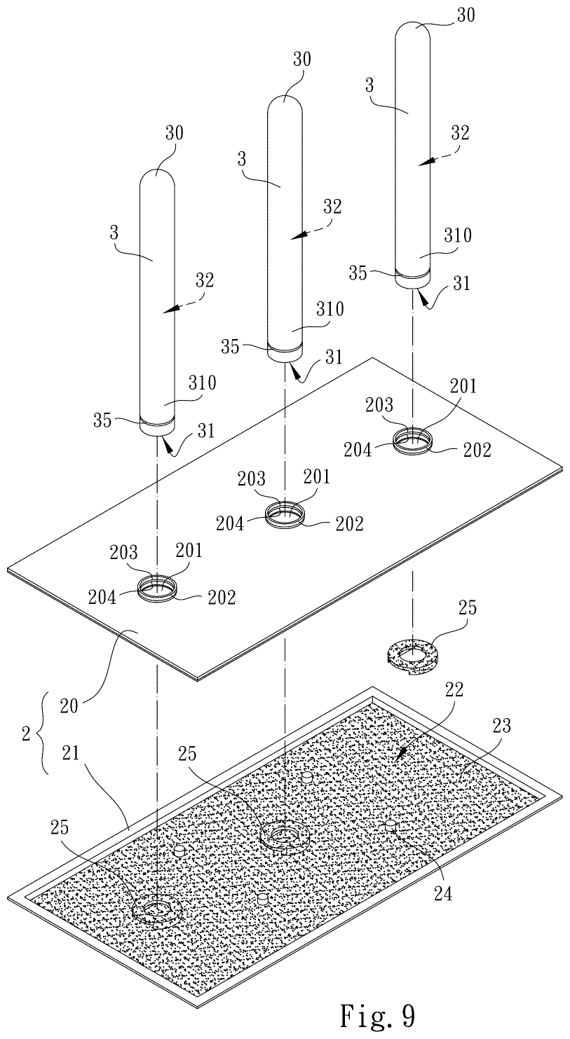

As shown in FIG. 6 through FIG. 11, the length between the second positioning portion 35 and the open end 31 of the heat pipe 3 is designed according to the configuration of the first wick structure 23. Especially, when the open end 31 is insertedly connected to the annular flange 202 and extends into the plate chamber 22 of the vapor chamber 2, the second wick structure 34 of the heat pipe 3 gets better contact with the first wick structure 23 of the vapor chamber 2. For example, as shown in FIG. 7 and FIG. 9, when the second positioning portion 35 of the heat pipe 3 is engaged with the first positioning portion 204 of the vapor chamber 2, the open end 31 of the heat pipe 3 is just in contact with the first wick structure 23 on the inner surface of the lower plate 21 of the vapor chamber 2, and the plate chamber 22 of the vapor chamber 2 communicates with the heat pipe chamber 32 of the heat pipe 3 via the notch 33 of the open end 31. The first wick structure 23 and the second wick structure 34 gets better contact with each other, so that the working fluid after being condensed and refluxed from the heat pipe chamber 32 flows smoothly through the second wick structure 34 to the first wick structure 23 for the evaporation region of the vapor chamber 2 to absorb the heat from the heat source to form a cycle.

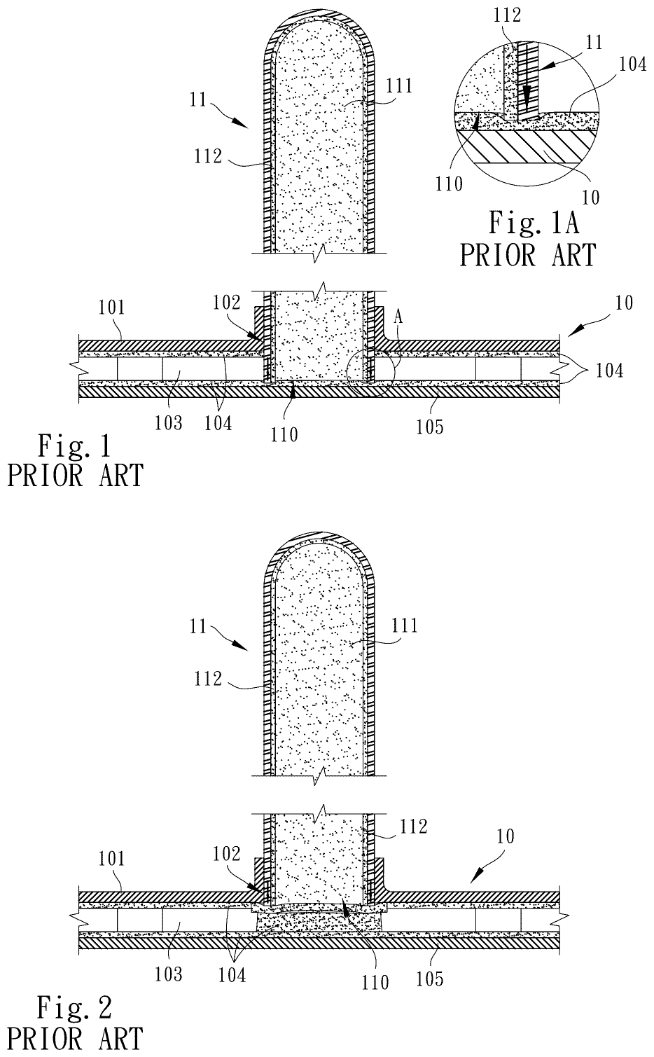

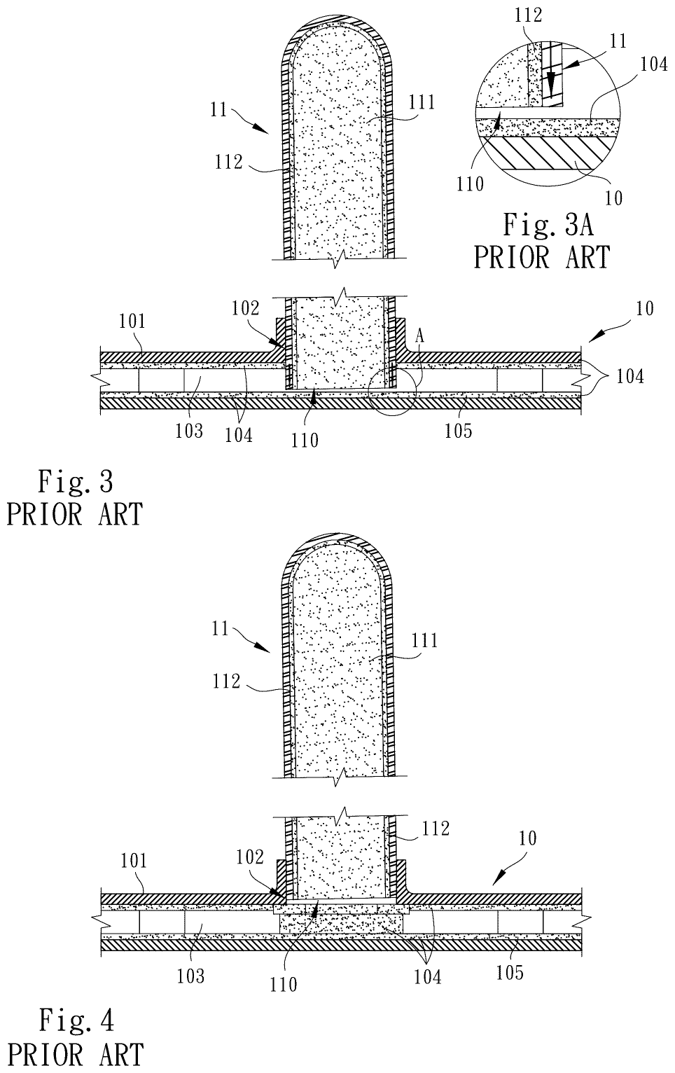

Compared with the prior art, as shown in FIG. 1, if the heat pipe 11 is inserted too deeply in the vapor chamber 10, the wick microstructure 104 in the vapor chamber 10 is damaged by the open end 110 of the heat pipe 11; as shown in FIG. 3 and FIG. 4, when the heat pipe 11 is inserted not enough in the vapor chamber 10, the wick microstructures 104, 112 of the vapor chamber 10 and the heat pipe 11 cannot get contact with each other effectively and are interrupted, so the working fluid condensed in the heat pipe 11 cannot flow back smoothly to the plate chamber 22 of the vapor chamber 10 to complete the cooling cycle, in the present invention, through the engagement of the first positioning portion 204 and the second positioning portion 35 to form a restriction for determining the depth of the open end 31 of the heat pipe 3 to be inserted into the vapor chamber 2, the first wick structure 23 gets better contact with the second wick structure 34 to avoid the defects and problems caused by the prior art.

FIG. 7 and FIG. 8 are schematic views according to a second embodiment of the present invention. In the second embodiment, when the first positioning portion 204 is engaged with the second positioning portion 35, the open end 31 of the heat pipe 3 is just extended to the through hole 201 of the upper plate 20 and no longer into the plate chamber 22, and the first wick structure 23 gets contact with second wick structure 34.

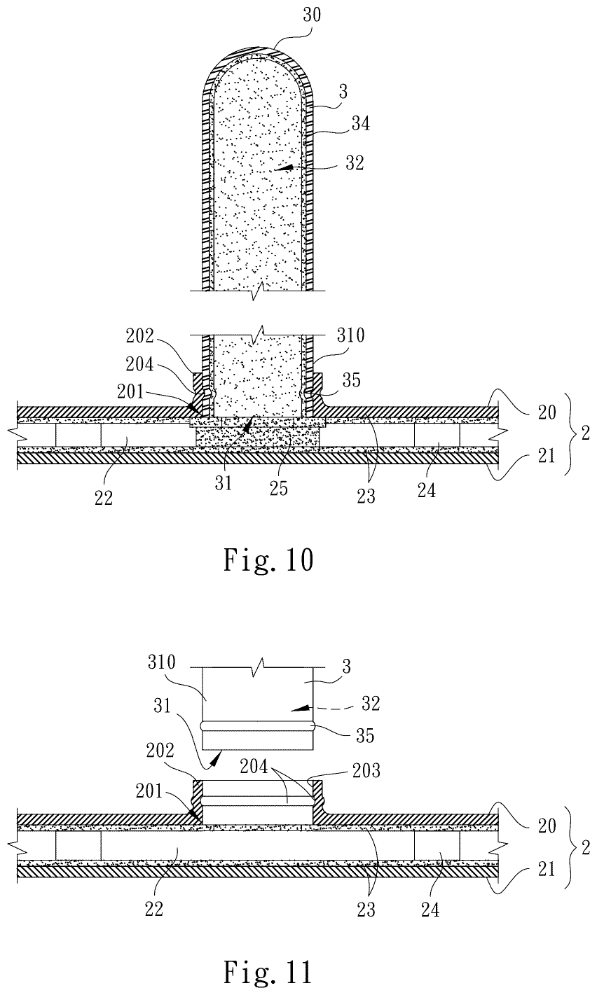

FIG. 9 and FIG. 10 are schematic views according to a third embodiment of the present invention. In the third embodiment, a support member 24 or a capillary member 25 is provided in the plate chamber 22 of the vapor chamber 2 and located below the through hole 201. The support member 24 or the capillary member 25 is in the form of a porous structure, and has two ends in contact with the first wick structure 23 and the second wick structure 34, respectively. When the first positioning portion 204 is engaged with the second positioning portion 35, the open end 31 is in contact with the top of the support member 24 or the capillary member 25, and the length between the second positioning portion 35 and the open end 31 is just enough to allow the first wick structure 23 to get better contact with the second wick structure 34.

In the embodiment of FIG. 7, the first positioning portion 204 is an annular convex portion protruding toward the center of the annular flange 202, that is, the first positioning portion 204 is an annular convex portion formed on the inner circumferential surface 203 of the annular flange 202. The second positioning portion 35 is an annular concave portion that is formed on the outer circumferential surface 310 of the heat pipe 3 close to the open end 31 and is concaved toward the center of the heat pipe 3.

FIG. 11 is a schematic view according to a fourth embodiment of the present invention. In the fourth embodiment, the first positioning portion 204 is an annular concave portion that is formed on the inner circumferential surface 203 of the annular flange 202 and concaved toward the inner circumferential surface 203. The second positioning portion 35 is an annular convex portion that is formed on the outer circumferential surface 310 of the heat pipe 3 close to the open end 31 and extends outwardly.

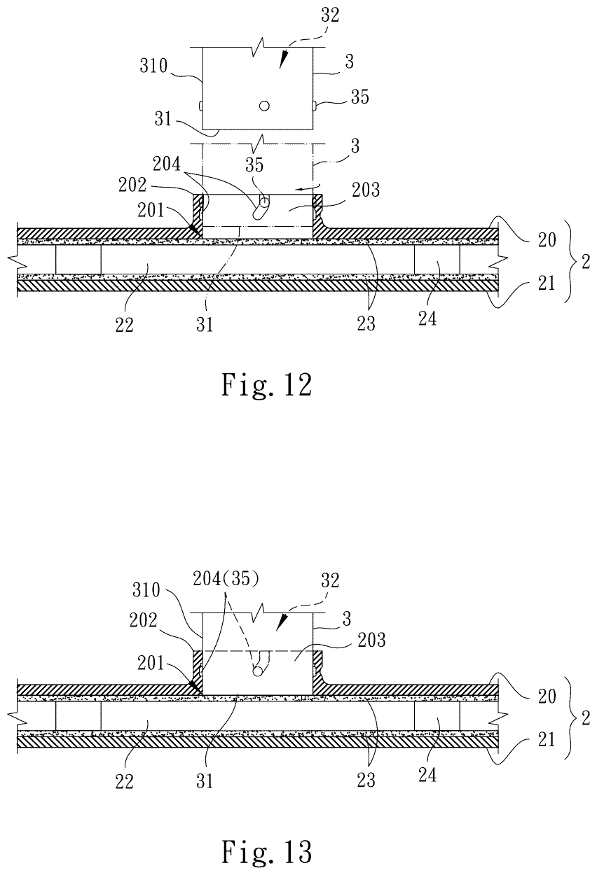

FIG. 12 and FIG. 13 are schematic views according to a fifth embodiment of the present invention. In the fifth embodiment, the first positioning portion 204 is in the form of three recesses that are formed on the inner circumferential surface 203 of the annular flange 202 and concaved toward the inner circumferential surface 203. The second positioning portion 35 is in the form of three protrusions that are formed on the outer circumferential surface 310 of the heat pipe 3 close to the open end 31. The number of the recesses of the first positioning portion 204 corresponds to the number of the protrusions of the second positioning portion 35.

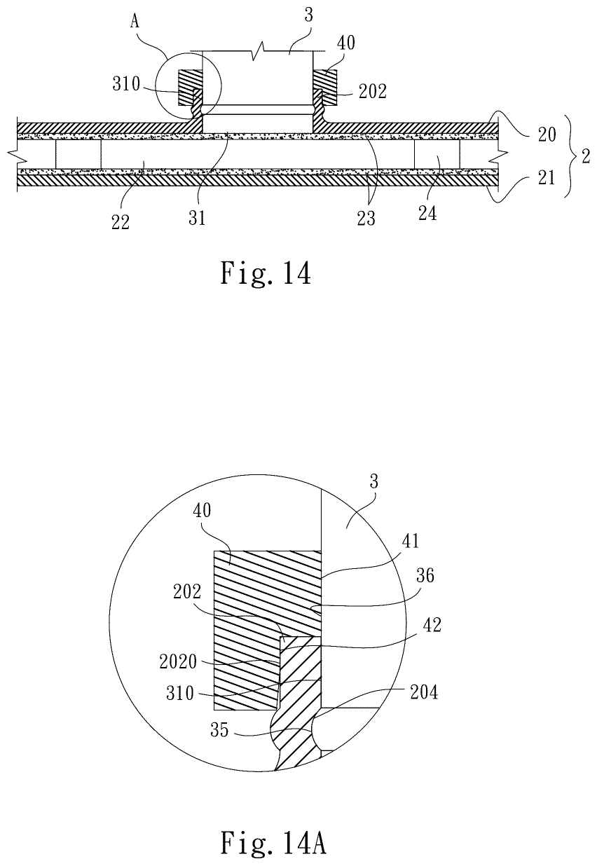

FIG. 14 and FIG. 14A are schematic views according to a sixth embodiment of the present invention. In the sixth embodiment, the opening of the annular flange 202 is fitted with a reinforcing collar 40. The reinforcing collar 40 is fitted on the periphery of the opening of the annular flange 202. The reinforcing collar 40 has a central hole 41 corresponding to an outer diameter 36 of the heat pipe 3 and an annular body having an inner diameter 42 corresponding to an outer diameter 2020 of the annular flange 202. When the first positioning portion 204 is engaged with the second positioning portion 35, the reinforcing collar 40 strengthens the structural strength of the opening of the annular flange 202, such that the heat pipe 3 is insertedly connected to the annular flange 202 accurately, uprightly and stably without being skewed,

In summary, through the first positioning portion 204 on the vapor chamber 2 and the second positioning portion 35 on the heat pipe 3 to be engaged with each other easily, the present invention can reduce or even completely avoid the error that the heat pipe 3 is inaccurately inserted in the vapor chamber 2 manually or blind-mate connection. The present invention allows for faster and more accurate positioning of the combination of the vapor chamber 2 and the heat pipe 3. The engagement of the first positioning portion 204 and the second positioning portion 35 forms a restriction and a basic support force on the junction of the vapor chamber 2 and the heat pipe 3, and has the function of assisting reprocessing and simplifying the assembly operation.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A combined heat dissipation structure, comprising:
a vapor chamber, including an upper plate and a lower plate, the lower plate being covered by the upper plate, a plate chamber being defined between the upper plate and the lower plate, a first wick structure being provided in the plate chamber, the upper plate having at least one through hole communicating with the plate chamber, an annular flange protruding outwardly from the through hole toward the upper plate, the annular flange having a first positioning portion; and
at least one heat pipe, having a heat pipe chamber therein, the heat pipe chamber communicating with the plate chamber, a second wick structure being provided in the heat pipe chamber, the heat pipe having two ends defined as a closed end and an open end, a second positioning portion being formed on the heat pipe close to the open end and corresponding in position to the second positioning portion;
wherein when the second positioning portion is engaged with the first positioning portion, a predetermined length between the second positioning portion and the open end is just for the open end to be located between the first positioning portion and the first wick structure on the lower plate and for the second wick structure of the heat pipe to get better contact with the first wick structure of the vapor chamber.

2. The combined heat dissipation structure as claimed in claim 1, wherein the first positioning portion is a convex portion annularly formed on an inner circumferential surface of the annular flange, and the second positioning portion is a concave portion annularly formed on an outer circumferential surface of the heat pipe close to the open end.

3. The combined heat dissipation structure as claimed in claim 1, wherein the first positioning portion is a concave portion annularly formed on an inner circumferential surface of the annular flange, and the second positioning portion is a convex portion annularly formed on an outer circumferential surface of the heat pipe close to the open end.

4. The combined heat dissipation structure as claimed in claim 1, further comprising one of a support member and a capillary member disposed in the plate chamber and located corresponding to the through hole, wherein the support member or the capillary member has two ends in contact with the first wick structure and the second wick structure, respectively.

5. The combined heat dissipation structure as claimed in claim 2, further comprising one of a support member and a capillary member disposed in the plate chamber and located corresponding to the through hole, wherein the support member or the capillary member has two ends in contact with the first wick structure and the second wick structure, respectively.

6. The combined heat dissipation structure as claimed in claim 3, further comprising one of a support member and a capillary member disposed in the plate chamber and located corresponding to the through hole, wherein the support member or the capillary member has two ends in contact with the first wick structure and the second wick structure, respectively.

7. The combined heat dissipation structure as claimed in claim 1, wherein the first wick structure and the second wick structure are selected from one of a sintered powder structure, a woven mesh, a grid and a fiber bundle.

8. The combined heat dissipation structure as claimed in claim 2, wherein the first wick structure and the second wick structure are selected from one of a sintered powder structure, a woven mesh, a grid and a fiber bundle.

9. The combined heat dissipation structure as claimed in claim 3, wherein the first wick structure and the second wick structure are selected from one of a sintered powder structure, a woven mesh, a grid and a fiber bundle.

10. The combined heat dissipation structure as claimed in claim 4, wherein the support member is in the form of a porous structure.

11. The combined heat dissipation structure as claimed in claim 5, wherein the support member is in the form of a porous structure.

12. The combined heat dissipation structure as claimed in claim 6, wherein the support member is in the form of a porous structure.

13. The combined heat dissipation structure as claimed in claim 1, further comprising a reinforcing collar fitted on an outer periphery of an opening of the annular flange.

14. The combined heat dissipation structure as claimed in claim 2, further comprising a reinforcing collar fitted on an outer periphery of an opening of the annular flange.

15. The combined heat dissipation structure as claimed in claim 3, further comprising a reinforcing collar fitted on an outer periphery of an opening of the annular flange.

16. The combined heat dissipation structure as claimed in claim 4, further comprising a reinforcing collar fitted on an outer periphery of an opening of the annular flange.

17. The combined heat dissipation structure as claimed in claim 10, further comprising a reinforcing collar fitted on an outer periphery of an opening of the annular flange.

18. The combined heat dissipation structure as claimed in claim 13, wherein the reinforcing collar has a central hole corresponding to an outer diameter of the heat pipe and an annular body having an inner diameter corresponding to an outer diameter of the annular flange.

19. The combined heat dissipation structure as claimed in claim 14, wherein the reinforcing collar has a central hole corresponding to an outer diameter of the heat pipe and an annular body having an inner diameter corresponding to an outer diameter of the annular flange.

20. The combined heat dissipation structure as claimed in claim 15, wherein the reinforcing collar has a central hole corresponding to an outer diameter of the heat pipe and an annular body having an inner diameter corresponding to an outer diameter of the annular flange.
